(19) United States
(12) Patent Application Publication
(10) Pub. No.: US 2026/0119732 A1
(43) Pub. Date: Apr. 30, 2026

(54) METHOD AND SYSTEM FOR DEVELOPING INTERIOR TRIM PARTS FOR A VEHICLE

(71) Applicant: FCA US LLC, Auburn Hills, MI (US)

(72) Inventors: Ramesh Babu Parthasarathy, Tamil Nadu (IN); Vigneshwara Mahaprabhu Lakshmanan, Tamil Nadu (IN); Kumaran Babu Kuttin Harimoorth, Tamil Nadu (IN); Seshram Ravindran, Tamil Nadu (IN)

(21) Appl. No.: 18/932,743

(22) Filed: Oct. 31, 2024

(51) Int. Cl. G06F 30/15

(52) U.S. Cl. CPC G06F 30/15

(57) ABSTRACT

A method and system of communicating an A-surface design signal for an interior part to a development tool through a network, determining, in a model of the development tool, a final design model for a B-surface of the interior part at development tool in response to an attachment parameter signal by determining an attachment type, determining an attachment thickness, determining a B-surface thickness, aligning an orientation of the attachment and selecting an attachment type, communicating the final design model to a validation system for analyzing the final design through the network to form a validated design and communicating the validated design to a design system through the network.

### FIELD

The present disclosure relates to interior trim, and, more specifically, to a method of developing interior trim parts for a vehicle.

### BACKGROUND

This section provides background information related to the present disclosure which is not necessarily prior art.

Interior trim components are located at various positions throughout a vehicle. The part development time for interior trim components under current practices may range from about four to eight weeks. This is due to changes in the A-surface for the component at multiple milestone levels. The process adds additional time during design, development and the validation phase. The design of interior trim components is manual and developed from the 3D computer-aided design (CAD) from the A-surface, which is the outer visible surface for plastic trim parts. CAD generation alone may take two to four weeks after the A-surface is released. Multiple iterations require the CAD to be updated based on simulation results which altogether is very time consuming.

The result of the lengthy process is that Tool kick-off timelines may not be met, and vehicle milestones may be affected. The last minute effort leads to shortage of resources that are available for other vehicle programs. The extended working hours and increase in manhour utilization leads to additional costs in the vehicle program and fatigue to the working engineers.

### SUMMARY

This section provides a general summary of the disclosure, and is not a comprehensive disclosure of its full scope or all of its features.

The present system and method provide a faster way to form a design for interior trim pieces. In a practical sense, this allows part to be developed before a tool kick-off timeline.

In one aspect of the disclosure, a method of communicating an A-surface design signal for an interior part to a development tool through a network, determining, in a model of the development tool, a final design model for a B-surface of the interior part at development tool in response to an attachment parameter signal by determining an attachment type, determining an attachment thickness, determining a B-surface thickness, aligning an orientation of the attachment and selecting an attachment type, communicating the final design model to a validation system for analyzing the final design through the network to form a validated design and communicating the validated design to a design system through the network.

In another aspect of the disclosure, a system includes a development tool comprising a model and a design system communicating an A-surface design signal for an interior part to the development tool through a network. The model of the development tool determines a final design model for a B-surface of the interior part at development tool in response to an attachment parameter signal by determining an attachment type, determining an attachment thickness, determining a B-surface thickness, aligning an orientation of the attachment and selecting an attachment type. The system has a validation system, and the development tool communicates the final design model through the network to the validation system for analyzing the final design to form a validated design and communicating the validated design to a design system through the network.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of a vehicle having trim components.

FIG. 2A is a perspective view of an attachment for a trim component illustrating the B-side.

FIG. 2B is a large portion showing the thickness of the attachment in FIG. 2A.

FIG. 2C is a perspective view illustrating a clip tower rib thickness.

FIG. 3 is a block diagrammatic view of the system.

FIG. 4 is a flowchart of the high level method utilizing the development tool set forth herein.

FIG. 5A is a flowchart of a method for building the development tool.

FIG. 5B is a flowchart for generating the processing code according to the present disclosure.

FIG. 6 is a flowchart of a method for using the development tool according to the present disclosure.

FIG. 7A is a graphically user interface for selecting the clips.

FIG. 7B is a user interface for selecting a single point or whole selection method.

FIG. 7C is a user interface for specifying the rotation of the clip stand or attachment.

FIG. 7D is a user interface for selecting rib thickness.

FIG. 7E is a user interface for selecting whether cross ribs are used.

FIG. 8A is a perspective view of a rear portion of a vehicle having a utility door.

FIG. 8B is a perspective view of an A-surface of an access door.

FIG. 8C is a perspective view of a B-surface of the access door.

FIG. 8D is a first example of an attachment.

FIG. 8E is a second example of an attachment used in FIG. 8C.

Corresponding reference numerals indicate corresponding parts throughout the several views of the drawings.

### DETAILED DESCRIPTION

Example embodiments will now be described more fully with reference to the accompanying drawings.

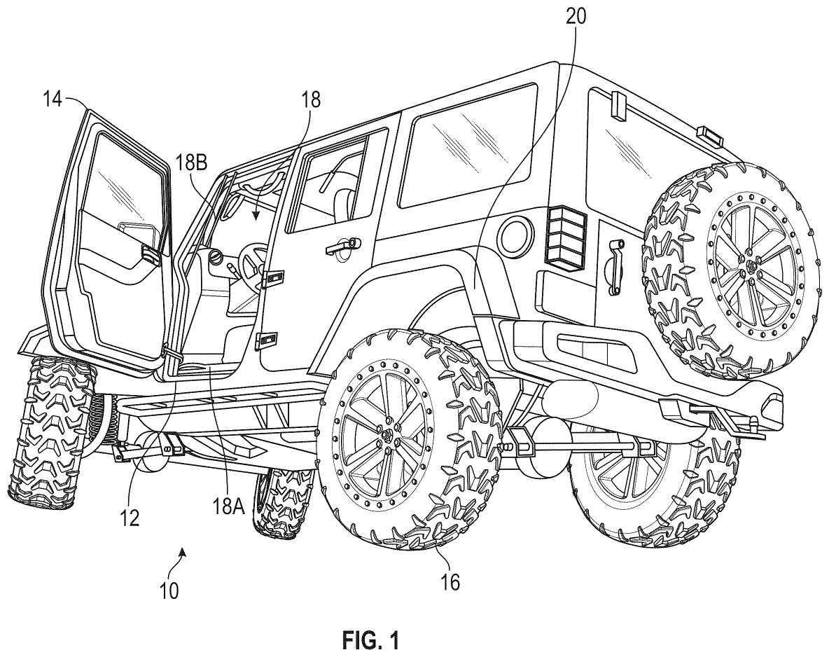

Referring now to FIG. 1, a vehicle 10 is illustrated having a body 12 that has doors 14 and wheels 16. The body 12 may be referred to as a body in white (BIW) when referring to the actual body structure itself even when fully painted for production. The vehicle 10 has interior trim components 18. The reference numeral 18 will refer to any interior trim components. However, trim components such as sill component 18A and an A pillar trim component 18B is specifically illustrated. The vehicle 10 may also include exterior trim components 20. One example of an exterior trim component 20 is a wheel arch component. Both the interior trim components 18 and the exterior trim components 20 may benefit from the teachings set forth herein. The teachings herein apply to both interior and exterior trim components.

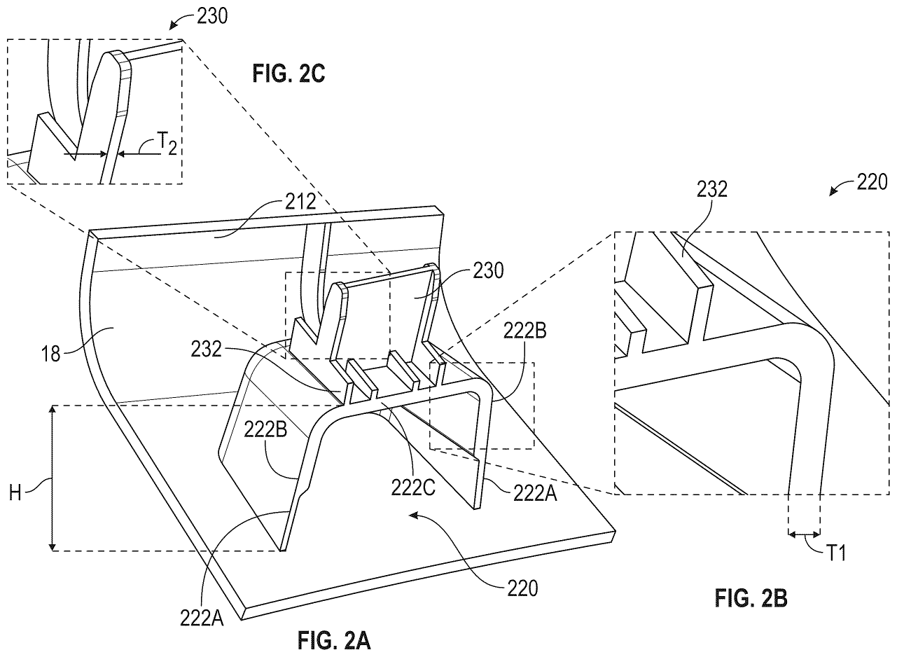

Referring now to FIG. 2A, one example of an interior trim component 18 is set forth. The trim component 18 has an A-surface 210 and a B-surface 212. The A-surfaces 210 are illustrated in FIG. 1 and correspond to the finished surface that is seen or touched by the customer. The B-surface 212 has attachments that are coupled thereto so that the interior trim component 18 can be coupled to the vehicle 10. Exterior trim components may have similar structures formed thereon.

The interior trim component 18 has a doghouse or attachment 220 extending therefrom. Typically, multiple attachments and multiple types of attachments may be provided. The doghouse or attachment 220 has legs 222. The legs 222 may have a narrow portion 222A and a wide portion 222B. That is, the thickness of the legs at the narrow portion 222A is less than the thickness of the leg at the wide portion 222B. FIG. 2B shows the thickness T₁ of the wide portion 222B. FIG. 2C shows a tower 230 extending from a cross-member 222C of the doghouse 220. The cross-member 222C extends between the legs 222. The cross-member 222C has the clip tower 230 extending therefrom. The clip tower 230 has ribs 232 extending from 222C. One rib in 230 and the thickness T₂ is illustrated enlarged in FIG. 2C. A portion 240 of the attachment 220 is illustrated in FIG. 2B. A portion 242 of the clip tower is illustrated in FIG. 2C.

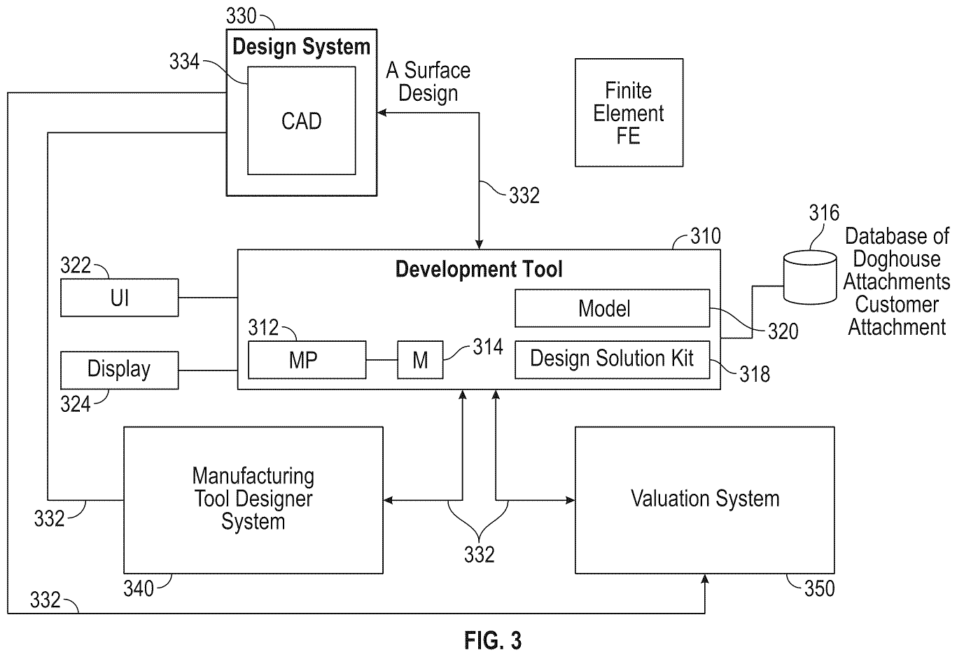

Referring now to FIG. 3, a development tool 310 is illustrated having a microprocessor or processor 312 and a memory 314. The microprocessor or processor 312 is used to perform the steps for operating the system. In particular, the memory 314 is a non-transitory computer-readable medium including machine-readable instructions that are executable by the processor 312. The development tool 310 may also be associated with a database 316 of various attachments or doghouse designs, the number of clips for an attachment, the types of clips and the like as will be described in greater detail below. The development tool 310 has a design solution kit 318 that is used to update the design based upon various parameters as described below. The development tool 310 has a B surface design generated from an A surface design model 320 which together form the trim component. The development tool 310 also has a user interface 322 that may be a keyboard, mouse, touch screen or the like that is used for inputting data and controlling the processing of the development tool. A display 324 is used for displaying various parameters and the like. A design system 330 is associated with the development tool 310. A network 332 communicates signals from the design system to the development tool. The design system may have a computer aided design (CAD) 334 that provides computer aided designs for the A-surface and for the body in white of the vehicle.

The design system 330, in addition to being coupled to the development tool through the network 332, may also be coupled to a manufacturing tool 340 through the network 332. The design system 330 may also be coupled to the validation system 350. Both the manufacturing tool designer system 340 and the validation system 350 may be in direct communication with the development tool 310. Signals may be exchanged through the network 332 between the development tool 310, the manufacturing tool designer system 340 and the validation system 350.

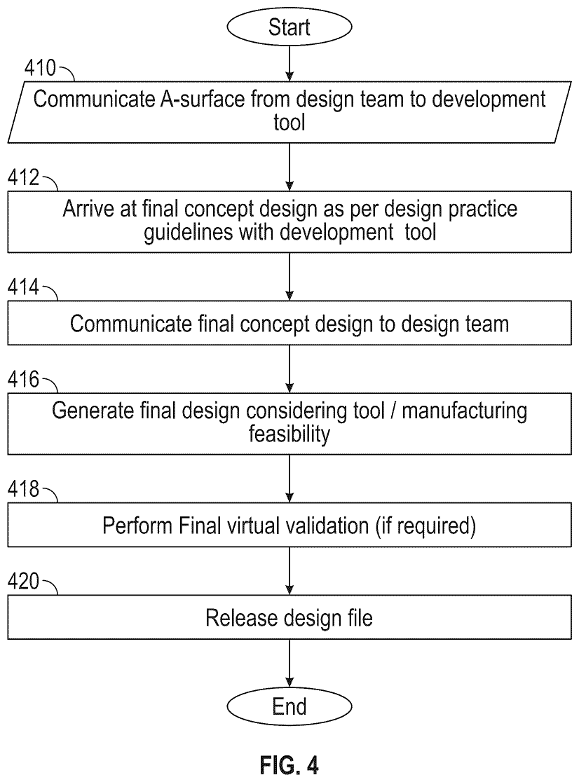

Referring now to FIG. 4, a high level block diagrammatic view of the process for designing an interior trim component. In step 410, the A-surface design is communicated in an A-surface design signal from the CAD system 334 of the design system 330. The A-surface design signal is communicated through the network 332 and corresponds to the A-surface only. The A-surface design signal is provided to the development tool 310. In step 412, a final design concept according to the present disclosure provides a final design concept for the entire interior trim component. That is, both the A-surface and B-surface together with any attachments, (doghouse), the attachment or doghouse position, the attachment approach, the thickness of the cross ribs and the like are provided in a final design signal. The process set forth in step 412 is described in greater detail below. Ultimately, a final concept design in the final design signal and is communicated to the design system in a final concept design signal. In step 416, the final concept design signal is used to generate a final design if manufacturing tools can be made for the final concept design and whether the final concept design is feasible for manufacturing. That is, the design system may be in communication with a manufacturing tool designer system. The development tool 310 may communicate the final concept design signal directly to the manufacturing tool designer system or communicate the final concept design signal to the design which, in turn, communicates the final concept design signal to the manufacturing tool designer system through the network 332.

A validation system 350 may perform final virtual validation of the final concept design in step 418. The validation system 350 may directly receive the final concept design signal. In step 420, the design file is released after validation. It should be noted that should any adjustments be required such as during the manufacturing feasibility or tool feasibility, changes may be made, and the updated design may be rechecked to determine whether tool and manufacturing feasibility is achieved as well as whether the design may be validated.

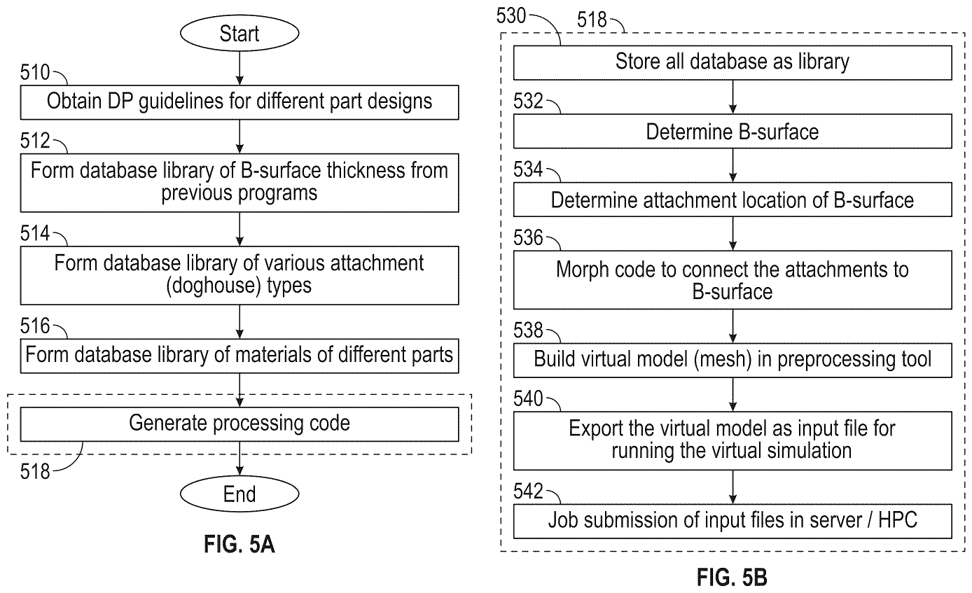

Referring now to FIG. 5, a method for generating the development tool of FIG. 3 is set forth in further detail. In step 510, design practice guidelines for different part designs are obtained. The design practice guidelines may be obtained from various sources. For example, certain companies may have information stored for recognitions for designing certain parts. In step 512, a database library of B-surface thickness from prior designs may be stored in the database. That is, a database may be formed from prior known products within a company. Companies may also share designs. Further, companies may obtain information by tearing competitor's vehicles and placing them in the database.

In step 514, a database library of various attachment types is set forth. The attachment types set forth herein are referred to as dog houses. In step 516, a database library for materials of different parts may be obtained. Various types and compositions of plastic and other types of material may be placed in the database 316. In step 518, the processing code for performing the design process is generated.

Referring now to FIG. 5B, the design process of step 518 is set forth in greater detail. In step 530, all of the databases are stored as a.

In step 532, the design for the B-surface is determined. The B-surface may be determined based upon the A-surface and other data that is received in the A-surface design signal from the CAD system. In step 534, the attachment location of the B-surface within the body of the vehicle is set forth. The code to connect the attachments to the B-surface is morphed in step 536. In step 538, a virtual mesh model may be built in a pre-processing tool. One example of a pre-processing tool is ANSA. ANSA is an advanced disciplinary CAE pre-processing tool that provides necessary functionality for full-model build up. The pre-processing tool, in step 538, may generate a mesh model. The mesh model may also be referred to as simulation input file to be used in the validation system. The virtual model may be used for running the virtual simulation in the validation system in step 540.

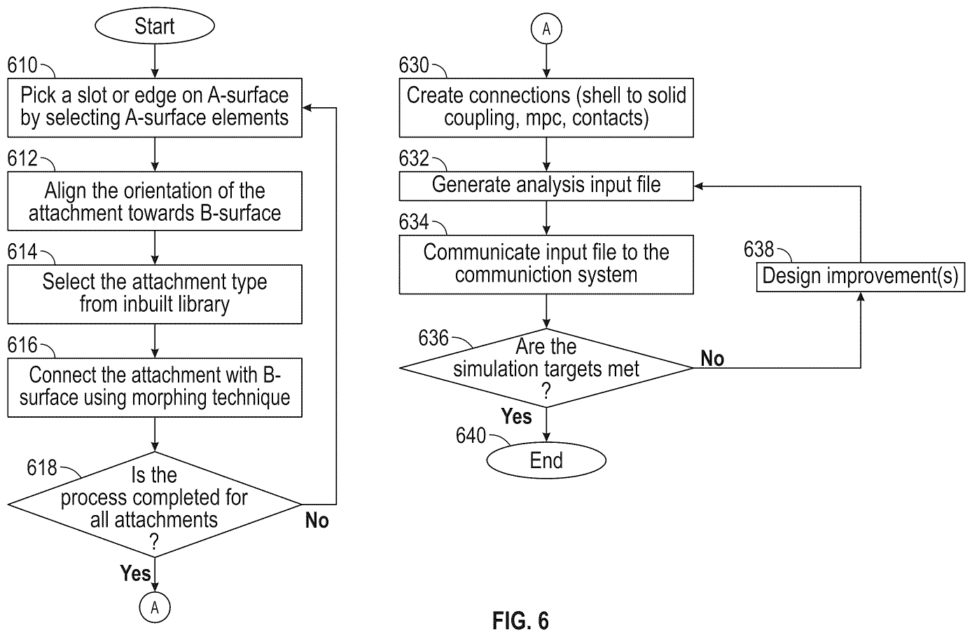

In step 542, the job submission of the input files is performed. That is, a high performance computing (HPC) system is used to receive a job submission which is communicated to the design through the network. Referring now to FIG. 6, the method of performing the design process with the development tool is set forth. In step 610, a slot on the BIW or an edge of an A-surface is obtained by selecting various surface elements on the A-surface. (. In step 612, the orientation of the attachment towards the B-surface is aligned. As mentioned above, the attachment may also be referred to as doghouse. In step 614, a select of an attachment type is selected based upon a received selection signal. In step 616, the attachment is connected with the B-surface using a morphing technique. Morphing refers to the process of smoothly transforming or interpolating the geometry of the attachment to fit or connect seamlessly with the B-surface. In step 618, it is determined whether the process is completed for all of the attachments. When all of the attachments have not been completed, step 610 is executed again. In step 618, when all of the processes have been completed for all of the attachments, step 630 is performed. In step 630, the connections are created like the shell to solid couplings, multi-point constraint and contacts. Information on step 632 is missing. In step 634, the input file is communicated to the validation system. As mentioned above, the process may be performed if the input file does not meet the validation requirement in step 636. If the requirements are not met in step 636, step 638 performs the processing. When the simulation targets are met, the process ends in step 640.

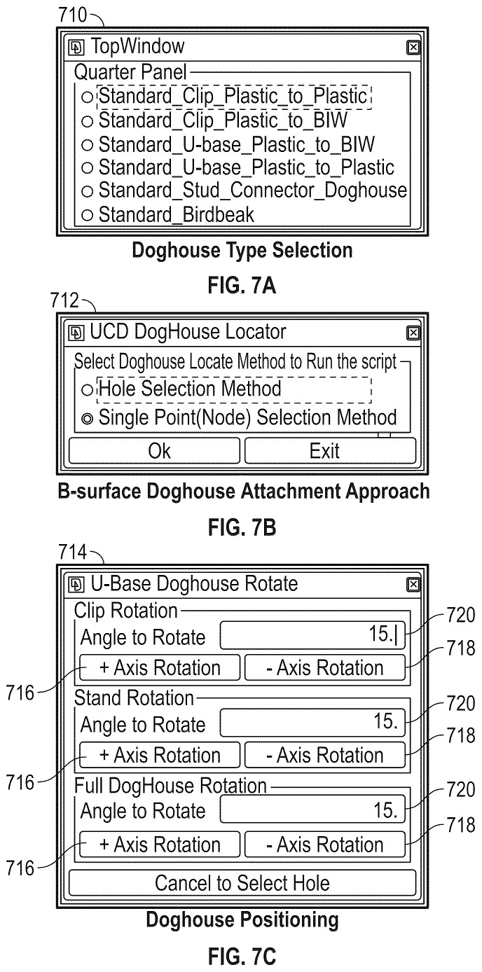

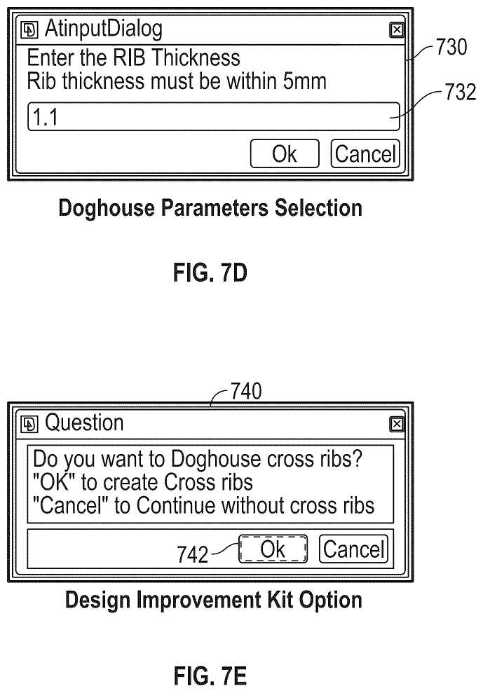

Referring now to FIG. 7A, a user interface 710 for selecting an attachment type for the B surface is illustrated. Signals corresponding to the selections are generated as inputs to the development tool 310. In this example, the quarter panel is one example of a trim piece. In this example, selections for standard clips coupled from plastic to plastic or plastic to body in white (BIW) are set forth therefor clip signals or slip selection signals are generated. Standard U-base clips may also be coupled from plastic to body in white or plastic to plastic. Standard stud connectors for the doghouse or attachment are also set forth. A standard bird beak may also be used. In each of the examples, clip, U-base or bird beak selection signals are generated when forming a selection on the user interface.

Referring now to FIG. 7BA, a doghouse locator user interface 712 is displayed. In this example, a hole selection method signal or a single point or node selection signal method may be generated. A signal corresponding to the whole selection or single point selection is communicated to the development tool from a user interface.

Referring now to FIG. 7C, a graphical user interface is used for selecting the clip rotation. That is, the clip rotation in the position or axis of rotation may be selected to form a clip rotation signal. Buttons 716 and 718 changes the direction of rotation. Amount of rotation can be directed in the display box 720. In this example, three sets rotation buttons 716, 718 are provided for each of the three choices for a clip rotation, stand rotation or full doghouse (attachment) rotation to form the corresponding angle to rotate selection signals.

In FIG. 7D, a graphical user interface 730 in which the rib thickness may be selected as a rib selection signal that is input into the input box 732.

Referring now to FIG. 7E, an interface 740 is set forth for selecting whether doghouse or attachment cross ribs are to be used. A selector 742 may be selected for enabling use of attachment cross ribs as a cross rib selector signal. All of the signals are provided to the model 320 so that a final design may be generated and validated.

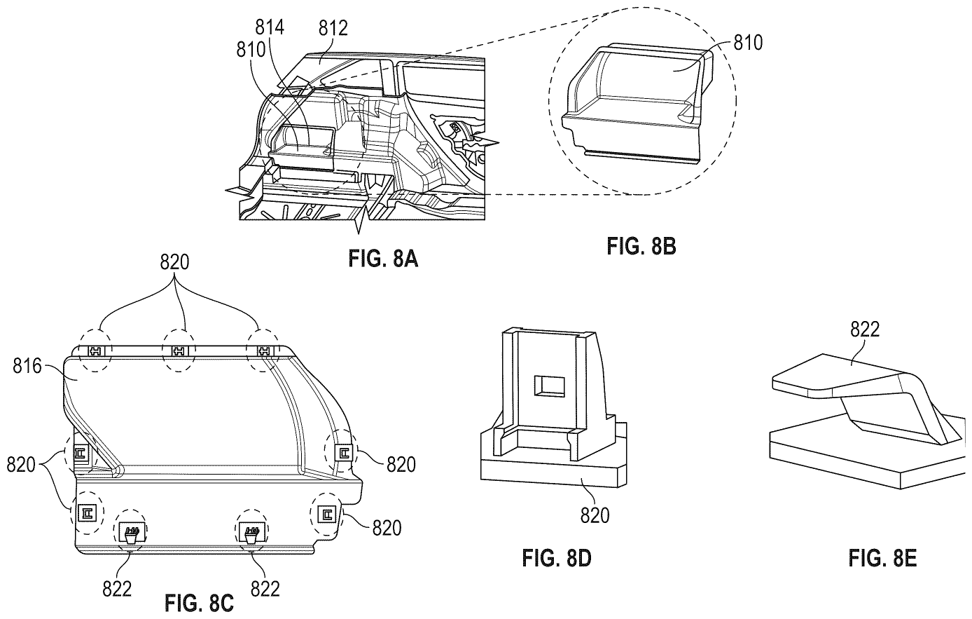

Referring now to FIGS. 8A-8E, the process may also be used for other trim pieces such as an access door 810 located in a rear portion 812 of a vehicle. The access door 810 has an A-surface 814 illustrated in FIG. 8B. A B-surface 816 is illustrated in FIG. 8C. In this example, seven doghouse attachments 820 are illustrated on the B-surface. The doghouse or attachment is illustrated in FIG. 8D. In FIG. 8C, two money clip attachments, as illustrated in FIG. 8E, are also provided on the B-surface.

As mentioned briefly above, by using the present process, the design can be arrived at early in the development program. Milestones may be met ahead of the specified timetables. Because multiple iterations are not required, the time savings has been achieved. Further, time is saved because the final design check for tool and manufacturability is only performed one time.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. 1steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method comprising:
communicating an A-surface design signal for an interior part to a development tool through a network;
determining, in a model of the development tool, a final design model for a B-surface of the interior part at development tool in response to an attachment parameter signal by determining an attachment type, determining an attachment thickness, determining a B-surface thickness, aligning an orientation of the attachment and selecting an attachment type;
communicating the final design model to a validation system for analyzing the final design through the network to form a validated design; and
communicating the validated design to a design system through the network.

2. The method of claim 1 wherein determining the attachment thickness comprises determining the attachment thickness at a leg.

3. The method of claim 1 wherein determining the attachment thickness comprises determining the attachment thickness at a leg having a first thickness and a second thickness.

4. The method of claim 1 wherein determining the final design comprises determining a number of clips.

5. The method of claim 1 wherein determining the final design comprises determining a type of clips.

6. The method of claim 1 wherein determining the final design comprises determining a first number of clips of a first type and a second number of clips of a second type.

7. The method of claim 1 further comprising generating a cross rib signal from a cross rib user interface and wherein determining the final design comprises adding cross ribs to the final design based on the cross rib signal.

8. The method of claim 1 further comprising generating a cross rib signal from a cross rib user interface and wherein determining the final design comprises adding cross ribs having a cross rib thickness to the final design based on the cross rib signal.

9. The method of claim 1 further comprising generating the attachment parameter signal by generating an attachment type signal.

10. The method of claim 9 wherein generating the attachment type signal comprises generating at least one of a clip signal, U-base signal, a standard U-base signal or a bird beak signal.

11. The method of claim 10 further comprising generating the attachment signal by generating an attachment positioning signal.

12. The method of claim 11 wherein generating the attachment positioning signal comprise generating one or more of a clip rotation signal, a stand rotation signal or an angle to rotation signal, a full attachment rotation signal.

13. The method of claim 11 further comprising generating the attachment parameter signal by generating an attachment approach signal.

14. The method of claim 13 wherein generating the attachment approach signal comprises generating a hole selection method signal or a single point selection method signal.

15. A system comprising:
a development tool comprising a model;
a design system communicating an A-surface design signal for an interior part to the development tool through a network;
the model of the development tool determining a final design model for a B-surface of the interior part at development tool in response to an attachment parameter signal by determining an attachment type, determining an attachment thickness, determining a B-surface thickness, aligning an orientation of the attachment and selecting an attachment type;
a validation system;
the development tool communicating the final design model through the network to the validation system for analyzing the final design to form a validated design and communicating the validated design to a design system through the network.

16. The system of claim 15 wherein the model determines the attachment thickness of a leg.

17. The system of claim 16 wherein the leg has a first thickness and a second thickness.

18. The system of claim 15 wherein the development tool determines the final design comprising a number of clips.

19. The system of claim 15 wherein the final design comprises a number of types of clips.

20. The system of claim 15 wherein the final design comprises a cross rib based on a cross rib signal of the development tool.
